(19) United States
(12) Patent Application Publication
(10) Pub. No.: US 2020/0232119 A1
(43) Pub. Date: Jul. 23, 2020

(54) METHOD OF FORMING SINGLE-CRYSTAL GROUP-III NITRIDE

(71) Applicants: CHUNG YUAN CHRISTIAN UNIVERSITY, Taoyuan City (TW); NATIONAL CHIAO TUNG UNIVERSITY, Hsinchu City (TW)

(72) Inventors: Jie-He CHEN, Taichung City (TW); Yu-Kai HSU, New Taipei City (TW); Xiang-Zhu XIE, Kaohsiung City (TW); Min-Jie LIOU, Yilan County (TW); Hui-Ling KAO, Taoyuan City (TW); Wen-Hao CHANG, Hsinchu City (TW); Jyh-Shin CHEN, Hsinchu City (TW); Po-Chun KUO, Taoyuan City (TW); Li-Syuan LU, Kaohsiung City (TW); Han YEH, Hsinchu County (TW)

(21) Appl. No.: 16/520,544

(22) Filed: Jul. 24, 2019

(30) Foreign Application Priority Data
Jan. 23, 2019 (TW) 108102615

(51) Int. Cl. C30B 29/40; C30B 25/06; C30B 25/18

(52) U.S. Cl. CPC C30B 29/403; C30B 25/18; C30B 25/06

(57) ABSTRACT

A method of forming a single-crystal group-III nitride is provided in the present invention. In some embodiments, the method includes the following steps. First, a molybdenum disulfide (MoS₂) is formed on a remote substrate. Then, the MoS₂ is transferred onto a substrate. Next, a sputtering operation is performed to epitaxially grow a single-crystal group-III nitride layer on the MoS₂, so as to form the single-crystal group-III nitride layer on the substrate such as a Si substrate or a flexible substrate.

### CROSS-REFERENCE TO RELATED APPLICATION

This application claims priority to Taiwan Application Serial Number 108102615, filed Jan. 23, 2019, which is herein incorporated by reference in its entirety.

### BACKGROUND

### Field of Invention

The present invention relates to a method of forming a single-crystal group-III nitride. More particularly, the present invention relates to a method for epitaxial growth of aluminum nitride.

### Description of Related Art

A material of a group-III nitride such as gallium nitride (GaN), indium nitride (InN), aluminum nitride (AlN) and their ternary compounds has a direct band gap and applies to a photoelectric device such as light-emitting diode or an optical detector. Also, a multi-layer structure of the group-III nitride induces a two-dimensional electron gas (2DEG) to be formed on their interfaces. Therefore, the group-III nitride is also applicable to a high-electron-mobility transistor. Moreover, GaN, AlN or the like has a great band gap with a greater breakdown voltage and applies to a high-power device.

Typically, the group-III nitride is formed by using a high-temperature growth, such as metal-organic chemical vapor deposition (MOCVD), molecular beam epitaxy (MBE) or the like, which causes high manufacture cost of the group-III nitride. Furthermore, the group-III nitride formed by using the high-temperature growth is easily cracked after being cooled down, due to the stress remaining in the group-III nitride. Besides, though the group-III nitride includes the aforementioned excellent properties, the group-III nitride is typically deposited on an expensive sapphire substrate in pursuit of better film quality and device performance. A dislocation density of 10¹⁰ cm⁻² may be achieved when the group-III nitride is deposited on the sapphire substrate but not on a silicon (100) substrate, because of the large lattice mismatch between the group-III nitride and the silicon (100) substrate.

To overcome the problem of the lattice mismatch between the group-III nitride and the silicon (100) substrate, a conventional method is to grow the group-III nitride on the Si (111) substrate. However, the lattice mismatch is still large, and the group-III nitride is easily cracked because of great stress caused by thermal expansion occurring between the interface of the Si (111) substrate and the group-III nitride layer. Another conventional method is provided, in which a graphene layer is transferred onto the silicon substrate as a buffer layer to grow the group-III nitride over the graphene layer. Although the conventional method can reduce the stress in epitaxy and may be used to manufacture devices on various substrates, the lattice mismatch between the graphene and the aluminum nitride is still large. As a result, the conventional method using the graphene as the buffer layer requires a higher growth temperature, and the aluminum nitride layer formed thereby is not a single-crystal aluminum nitride layer.

Accordingly, there is a need to provide a method of forming a single-crystal group-III nitride with satisfactory quality, and the single-crystal group-III nitride is formed on a low-cost substrate (e.g., a silicon substrate) under low temperature.

### SUMMARY

An aspect of the present invention is to provide a method of forming a single-crystal group-III nitride. In some embodiments, the method includes the following operations. First, molybdenum disulfide (MoS₂) is formed on a remote substrate. Next, the MoS₂ is transferred onto a substrate. Then a sputtering operation is performed on the MoS₂, in which the mixture gas of nitrogen gas and inert gas is introduced, and the plasma of the mixture gas is formed to bombard the aluminum target, thereby epitaxially depositing a single-crystal group-III nitride layer on the MoS₂.

In accordance with some embodiments of the present invention, the sputtering operation is performed under a working pressure of 1.2×10⁻² pa to 2.6×10⁻² pa.

In accordance with some embodiments of the present invention, forming the MoS₂ includes placing the remote substrate in a reaction chamber and introducing molybdenum (Mo)-containing precursor and sulfur (S)-containing precursor into the reaction chamber, thereby depositing the MoS₂ on the remote substrate.

In accordance with some embodiments of the present invention, the substrate includes a silicon substrate, a flexible substrate, a sapphire substrate or a silicon carbide substrate.

In accordance with some embodiments of the present invention, the sputtering operation is performed under a background pressure that is equal to or smaller than 7.0×10⁻⁵ pa.

In accordance with some embodiments of the present invention, the power on the aluminum target in the sputtering operation is 100 W to 200 W.

In accordance with some embodiments of the present invention, the ratio of the flow rate of the inert gas to the flow rate of the nitrogen gas is 3:1 to 1:3.

In accordance with some embodiments of the present invention, the thickness of the MoS₂ is in a range from 0.7 nm to 2.5 nm.

In accordance with some embodiments of the present invention, the method further includes forming a gallium nitride layer on the single-crystal group-III nitride layer. No operation with the reaction temperature greater than 500° C. is performed between forming the single-crystal group-III nitride layer and forming the gallium nitride layer.

In accordance with some embodiments of the present invention, the single-crystal group-III nitride layer is c-axis oriented aluminum nitride (AlN).

### BRIEF DESCRIPTION OF THE DRAWINGS

Copies of this patent or patent application publication with color drawings will be provided by Office upon request and payment of the necessary fee. The disclosure can be more fully understood by reading the following detailed description of the embodiment, with reference made to the accompanying drawings as follows.

FIG. 1A through FIG. 1G are schematic views of various intermediate stages showing a method of forming a single-crystal group-III aluminum nitride in accordance with some embodiments of the present invention.

FIG. 2 is an X-ray diffraction (XRD) spectrum in the θ-2θ scan of a single-crystal aluminum nitride layer of an example.

FIG. 3 is an XRD spectrum in the φ scan of a single-crystal aluminum nitride layer of an example.

FIG. 4 is a high-resolution transmission electron microscopy (TEM) image of an AlN/MoS₂/Si structure of an example.

FIG. 5 shows the XRD rocking curves of aluminum nitrides formed by various methods.

### DETAILED DESCRIPTION

Because of having a hexagonal crystal structure, the c-axis oriented single-crystal aluminum nitride can only be grown on a material layer with the same hexagonal crystal structure. However, a silicon substrate (e.g., Si(100)) lacks the hexagonal crystal structure, and a large degree of lattice mismatch exists between the silicon substrate and the group-III nitride. To reduce the lattice mismatch between the aluminum nitride and the silicon substrate, a buffer layer may be inserted between the aluminum nitride and the silicon substrate. For example, the buffer layer may be formed by graphene or molybdenum disulfide (MoS₂). However, the degree of the lattice mismatch between the graphene and the aluminum nitride is still about 26.5%, such that the single-crystal aluminum nitride layer cannot be grown on the graphene layer. Moreover, the MoS₂ directly formed on the silicon substrate does not have the hexagonal crystal structure, although the degree of the lattice mismatch between the MoS₂ and the aluminum nitride is small (about 1.6%). Apparently, a method is needed for first forming the MoS₂ layer with the hexagonal crystal structure, and then enabling the c-axis-oriented single-crystal aluminum nitride to be formed on the MoS₂ layer.

An aspect of the present invention is directed to providing a method of forming a single-crystal group-III nitride. In some embodiments, the present invention includes forming the MoS₂ layer having the hexagonal crystal structure over an amorphous substrate or a substrate having large lattice mismatch to MoS₂ (or aluminum nitride), and forming the c-axis oriented single-crystal aluminum nitride on the MoS₂ layer under a lower process temperature.

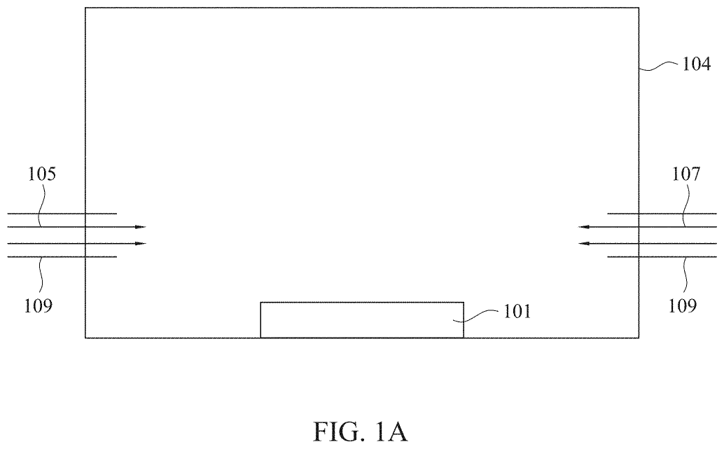

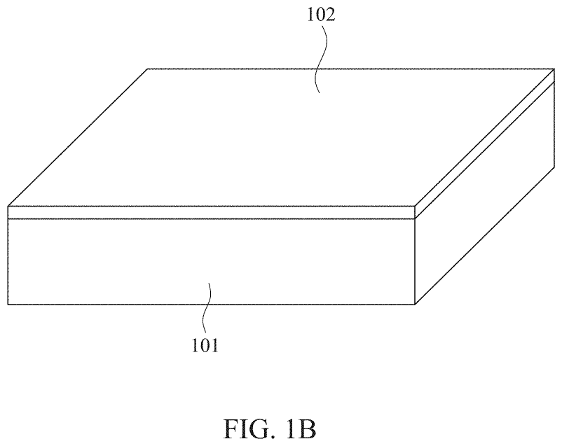

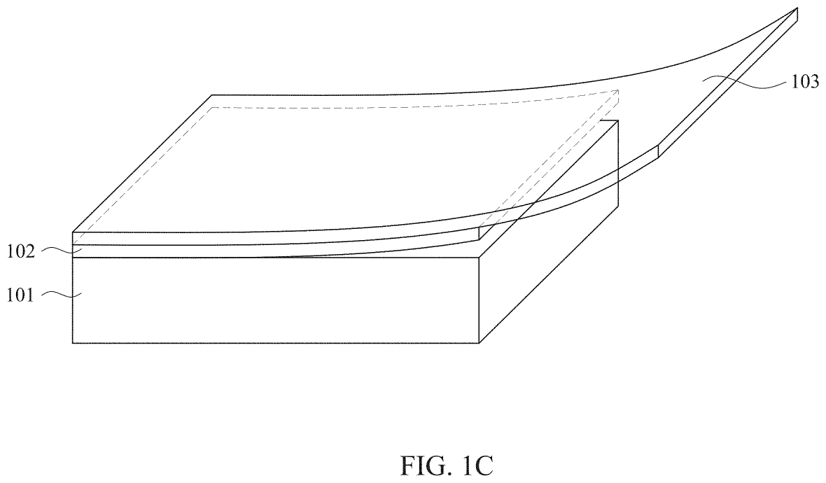

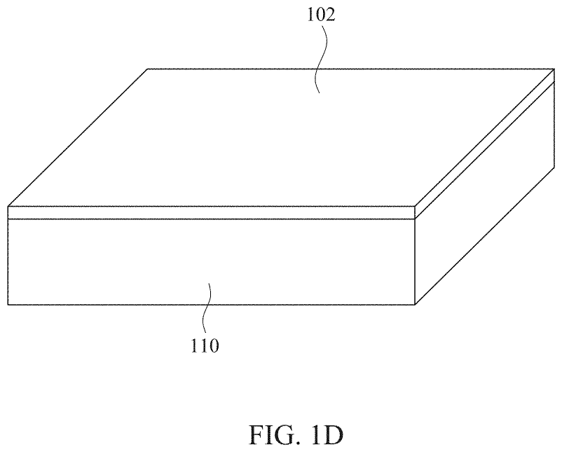

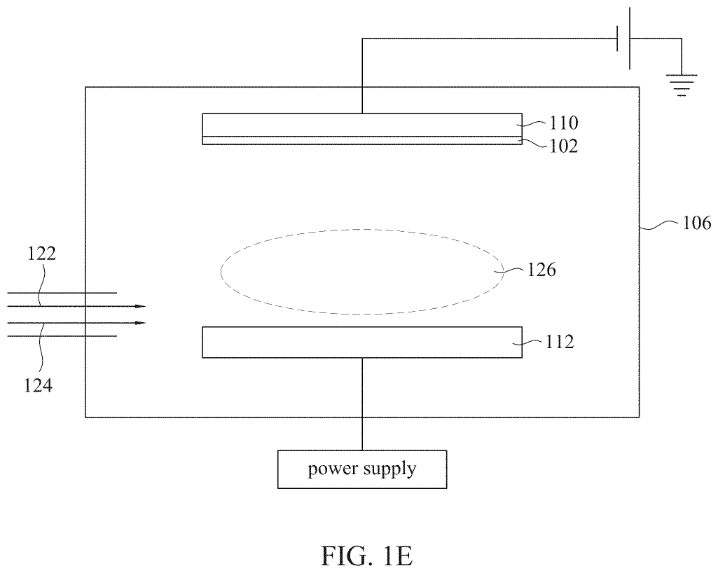

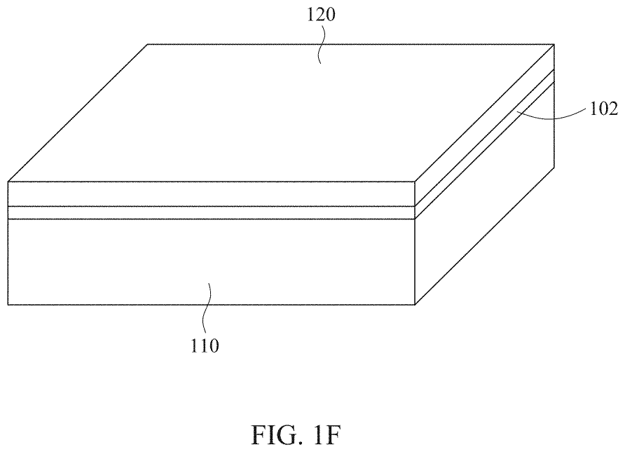

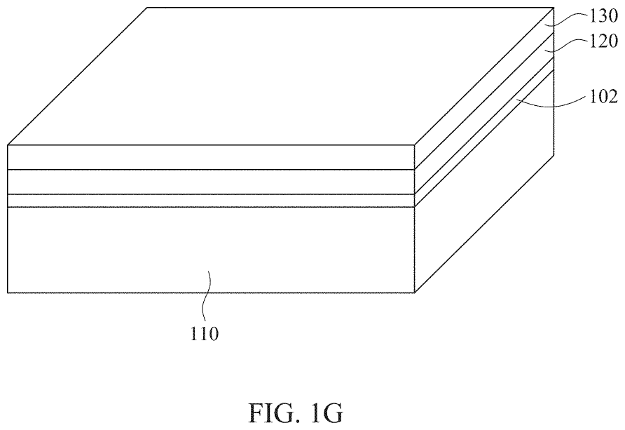

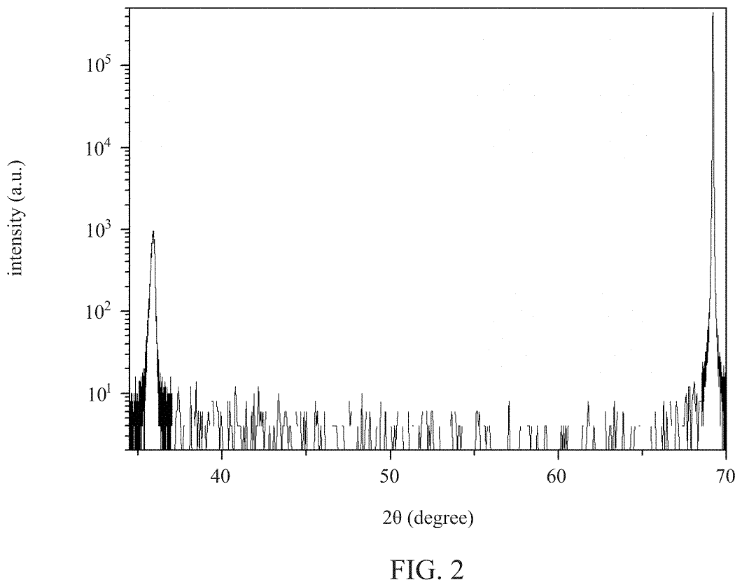

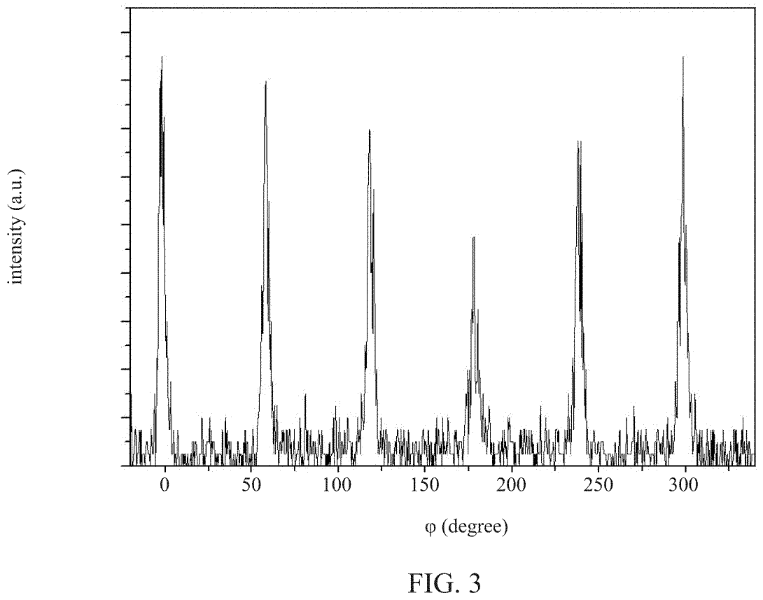

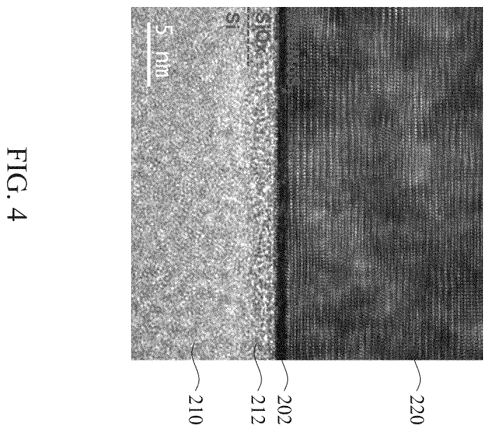

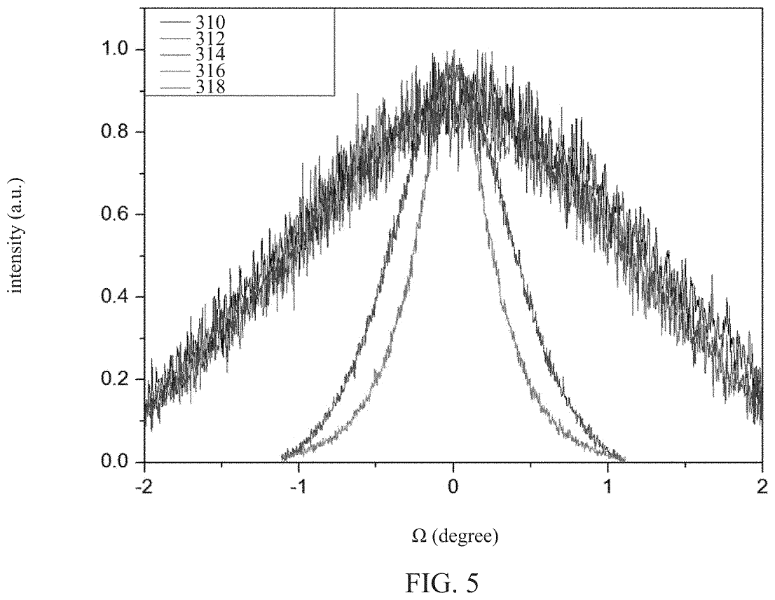

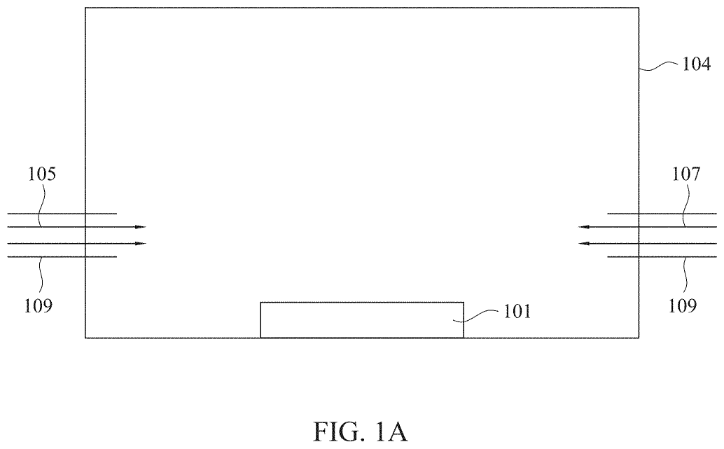

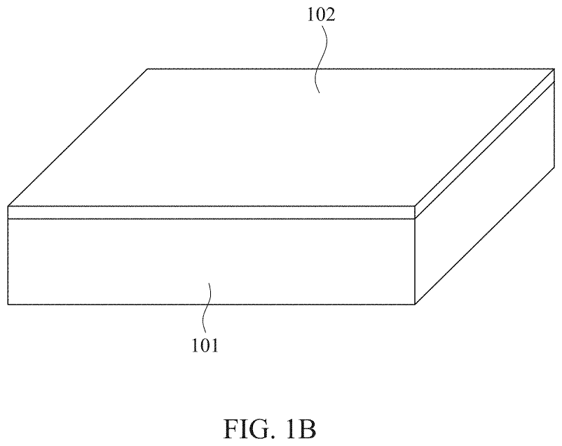

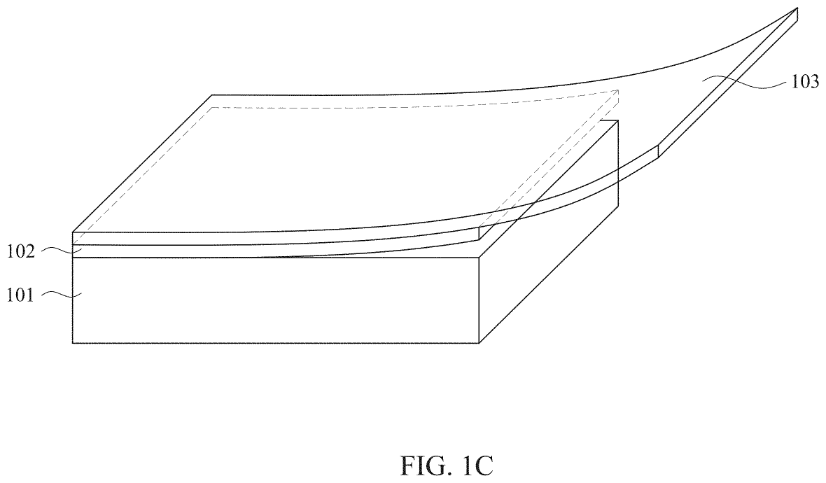

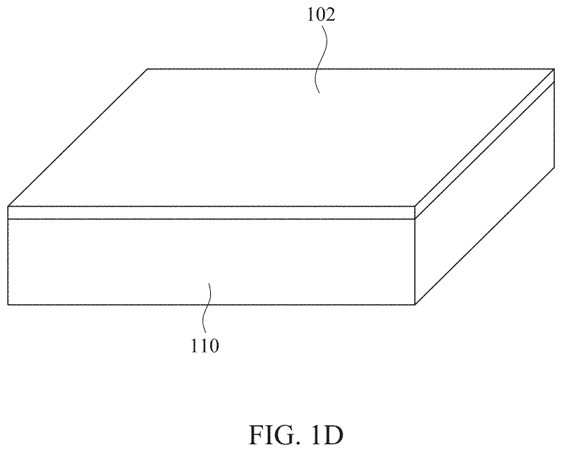

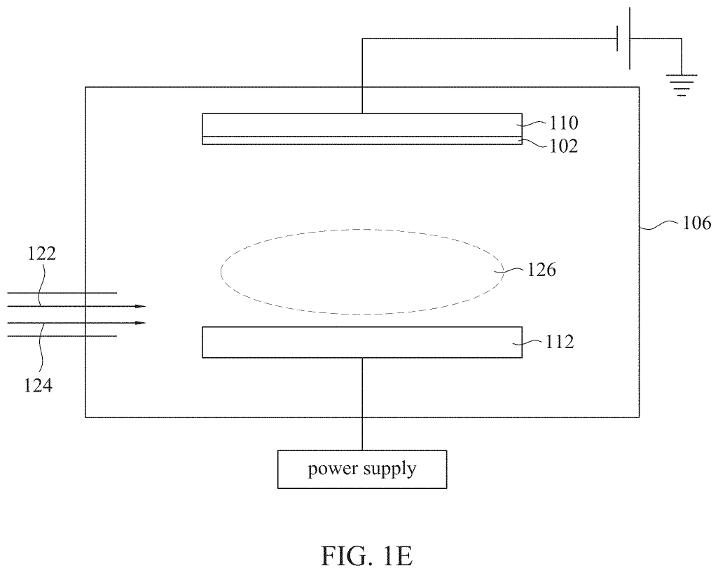

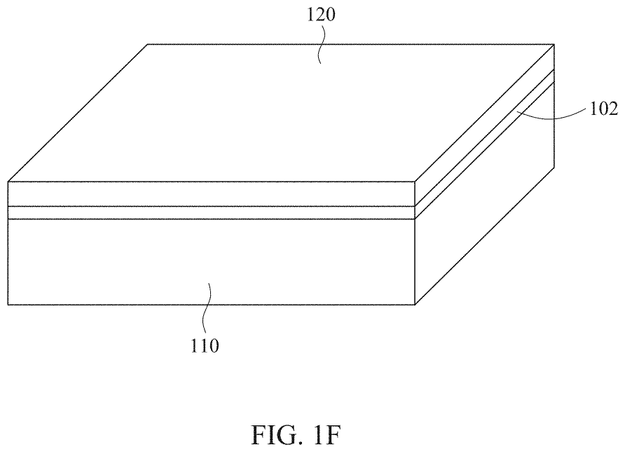

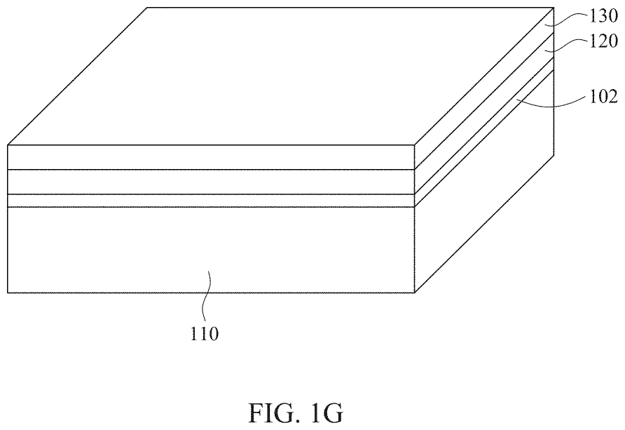

Please refer to FIG. 1A through FIG. 1G. FIG. 1A through FIG. 1G are schematic views of various intermediate stages showing a method of forming a single-crystal group-III aluminum nitride, in which FIG. 1A and FIG. 1E are cross-sectional views, and FIG.1B through FIG.1D, FIG. 1F and FIG. 1G are three-dimensional (3D) views. In some embodiments, as shown in FIG. 1A and FIG. 1B, the method includes forming a MoS₂ 102 on a remote substrate 101. The term “remote substrate” 101 of the present invention may be referred to as another substrate that is different from a substrate 110 (FIG. 1D) on which a single-crystal group-III nitride 120 is formed. In other words, the MoS₂ 102 is not directly formed on the substrate 110 on which the single-crystal group-III nitride 120 formed subsequently. Instead, the MoS₂ 102 is first grown on another substrate and then is transferred onto the substrate 110 on which the single-crystal group-III nitride 120 is formed subsequently. The remote substrate 101 may include but is not limited to a metal substrate or a sapphire substrate. The metal substrate may be, for example, a copper substrate.

In some embodiment, the MoS₂ 102 is formed on the remote substrate 101 by chemical vapor deposition (CVD). In certain examples, as shown in FIG. 1A, the remote substrate 101 is placed in a reaction chamber 104, molybdenum(Mo)-containing precursor 105 and sulfur(S)-containing precursor 107 are introduced into the reaction chamber 104. Argon gas or a mixture gas of the argon gas and oxygen gas may be used as a carrier gas 109 for introducing the precursors. A flow rate of the carrier gas 109 may be, for example, 70 SCCM to 110 SCCM. In some examples, the Mo-containing precursor 105 is formed by heating the powder of molybdenum oxide (MoO₃) at 700° C. to 750° C. and the S-containing precursor 107 is formed by heating the powder of sulfur at 115° C. to 135° C. In other embodiments, heating the remote substrate 101 at 800° C. to 900° C. may benefit the formation of the MoS₂ 102. In some embodiments, a molar ratio of the Mo-containing precursor 105 to the S-containing precursor 107 may be 1:1 to 1:3.

In further embodiments, the deposition operation may be performed for 5 minutes to 30 minutes, to form the MoS₂ 102 having one to three atomic layers, and the thickness of the one to three atomic layers may range from about 0.7 nm to 2.5 nm. The MoS₂ 102 has the hexagonal crystal structure, and defects caused by the lattice mismatch between two adjacent layers may be reduced because the MoS₂ 102 is thinner and has a less number of atomic layers. As a result, the group-III nitride to be formed on the MoS₂ 102 may have properties such as the single crystal and c-axis orientation.

Next, as shown in FIG. 10 and FIG. 1D, the remote substrate 101 that the MoS₂ 102 is deposited thereon is moved out from the reaction chamber 104, and the MoS₂ 102 is transferred from the remote substrate 101 onto the substrate 110. In some embodiments, the operation of transferring the MoS₂ 102 may include removing the MoS₂ 102 from the remote substrate 101, as shown in FIG. 10. For example, a polymer film 103 covers the MoS₂ 102 on the remote substrate 101, and the polymer film 103 and the MoS₂ 102 are collectively clamped and removed from the remote substrate 101 by using a stepping motor and a robot arm (not shown). The polymer film 103 may include but is not limited to polydimethylsiloxane (PDMS), poly(methyl methacrylate) (PMMA) and the like.

In some embodiments, the operation of transferring the MoS₂ 102 also includes disposing the MoS₂ 102 on the substrate 110, as shown in FIG. 1D. In certain embodiments, the operation of disposing the MoS₂ 102 on the substrate 110 may be performed using the stepping motor and the robot arm to dispose the polymer 103 and the MoS₂ 102 on the substrate 110, in which the MoS₂ 102 contacts the substrate 110. Then, the polymer film 103 may be torn off and the MoS₂ 102 remains on the substrate 110.

In other embodiments, for example, the MoS₂ 102 may be stripped from the polymer film 103 by using an etching method, and then the MoS₂ 102 may be disposed on the substrate 110. Specifically, a composite film of the polymer film 103 and the MoS₂ 102 is immersed in an alkaline solution such as potassium hydride solution (KOH) at 85° C. to 90° C. Then, the composite film of the polymer film 103 and the MoS₂ 102 is immersed in deionized water, so that the MoS₂ 102 may be stripped from the polymer film 103. The substrate 110 is then dipped in the deionized water such that the MoS₂ 102 floating on the deionized water is transferred onto the substrate 110.

The MoS₂ 102 having the desired hexagonal crystal structure can be formed on the substrate 110 regardless of the arrangement of the crystal lattice of the substrate 110 because of the transferring operation. In some embodiments, the substrate 110 may include a silicon substrate, a flexible substrate, a sapphire substrate or a silicon carbide substrate. The flexible substrate may include a substrate formed from a variety of resin materials. In certain embodiments, the silicon substrate or the flexible is preferable for use as the substrate 110 to lower down the manufacturing cost of the single-crystal group-III nitride.

In some embodiments, before the formation of the MoS₂ 102, the remote substrate 101 may be washed by using an organic solvent (e.g., acetone) and deionized water, and then dried by a baking operation. In some embodiments, before the MoS₂ 102 is transferred, the substrate 110 may be washed by using an organic solvent (e.g., acetone, methanol, isopropanol) and deionized water, and then dried by a baking operation.

Afterward, as shown in FIG. 1E and FIG. 1F, a single-crystal group-III nitride layer 120 is epitaxially grown (or is deposited) on the MoS₂ 102 in a reaction chamber 106. It is noted that the structure of FIG. 1F may be still placed in the reaction chamber 106 for subsequent deposition of other layers; or, the structure of FIG. 1F may be moved out from the reaction chamber 106 to other chambers after the structure of FIG. 1F is formed. In some embodiments, a sputtering operation may be performed to form the single-crystal group-III nitride layer 120 in the reaction chamber 106. The sputtering operation is performed by introducing the mixture gas of nitrogen gas 122 and an inert gas 124 into the reaction chamber 106, and the plasma 126 of the mixture gas is formed to bombard the aluminum target 112, such that the single-crystal group-III nitride layer 120 is epitaxially grown on the MoS₂ 102. The sputtering operation is performed at a temperature preferably from 300° C. to 500° C. Besides, the sputtering operation may be performed under a working pressure of 1.2×10⁻² pa to 2.6×10⁻² pa. As the working pressure is greater than 2.6×10⁻² pa, the single-crystal structure may not be formed; while, as the working pressure is smaller than 1.2×10⁻² pa, the apparatus cost would greatly increase. As the temperature is higher than 500° C., thermal stress may be accumulated in the single-crystal group-III nitride layer 120, such that the single-crystal group-III nitride layer 120 may be easily cracked after it is cooled down; while, as the temperature is lower than 300° C., the single-crystal group-III nitride layer 120 may not be formed (the formed nitride may be amorphous). The inert gas 124 may be, for example, argon gas. The ratio of the flow rate of the inert gas 124 to the flow rate of the nitrogen gas 122 is 3:1 to 1:3. The quality of the single-crystal group-III nitride layer 120 may be improved by controlling a reaction rate using the said particular ratio.

In some embodiments, the sputtering operation is performed under a background pressure that is equal to or smaller than 7.0×10⁻⁵ pa. As the background pressure is greater than 7.0×10⁻⁵ pa, a great number of impurities in the reaction chamber 106 may have an impact on the quality of the single-crystal group-III nitride. Besides, the sputtering operation may be performed using a power of 100 W to 200 W on the aluminum target.

In some embodiments, the sputtering operation includes radio frequency magnetron sputtering, direct current sputtering or helicon sputtering. In certain embodiments, the sputtering operation is performed by the helicon sputtering with coil power of greater than 0 W and equal to 100 W. By using the particular coil power, a localized magnetic field generated after the coil is energized can increase the moving path of secondary electrons, such that the mean free path of ions of the sputtering operation can be increased and the single-crystal group-III nitride can be formed. In some embodiments, the single-crystal group-III nitride layer 120 is c-axis oriented aluminum nitride. In some embodiments, the thickness of the single-crystal group-III nitride layer 120 is 300 nm to 500 nm.

In some embodiments, the method of forming the single-crystal group-III nitride of the present invention excludes a method of forming the single-crystal group-III nitride using a temperature higher than 500° C. (e.g., metal-organic chemical vapor deposition; MOCVD), because the aluminum nitride formed by using such high temperature is easily cracked after it is cooled down. The crack of the aluminum nitride has resulted from the stress remaining in the aluminum nitride.

Next, as shown in FIG. 1G, the method of forming the single-crystal group-III nitride may further include forming a gallium nitride (GaN) layer 130 on the single-crystal group-III nitride layer 120. In some embodiments, the GaN layer 130 may be deposited by using MOCVD. For example, hydrogen gas, nitrogen gas and gallium-containing precursor may be introduced at about 900° C. to about 1100° C. The GaN layer 130 may be formed by any typical method, and the present invention is not limited to the disclosed method.

In some embodiments, before the GaN layer 130 is formed and after the single-crystal group-III nitride layer 120 is formed (i.e., the operation between the operation of forming the GaN layer 130 and the operation of forming the single-crystal group-III nitride layer 120), no operation with a reaction temperature greater than 500° C. is performed. In other embodiments, the GaN layer 130 is formed immediately after the single-crystal group-III nitride layer 120 is formed.

### EXAMPLE

0.2 g of MoO₃ and 0.155 g of a sulfur powder were respectively heated at 750° C. and 135° C. to form the Mo-containing precursor and the S-containing precursor. Argon gas with the flow rate of 90 SCCM was introduced as a carrier gas, and the precursors were introduced into a reaction chamber by using the carrier gas at 750° C., in which a sapphire substrate was placed in the reaction chamber. The Mo-containing precursor was reacted with the S-containing precursor for 10 minutes, thereby forming MoS₂ having the thickness of about 1 nm on the sapphire substrate. Next, the sapphire substrate was taken out from the reaction chamber and cooled down, and the MoS₂ was then transferred from the sapphire substrate onto a silicon substrate by using a PDMS polymer film. Then, the silicon substrate (Si(100)) having the MoS₂ thereon was disposed into another reaction chamber under a background pressure of 7×10⁻⁵ pa, and the temperature of the reaction chamber raised to 400° C. Afterward, argon gas (99.9999% purity) and nitrogen gas (99.9995% purity) were introduced to the reaction chamber, such that a working pressure of the reaction chamber was 1.2×10⁻² pa, in which the ratio of the flow rate of the argon gas to the flow rate of the nitrogen gas is 1:1. Then, the power on the target was adjusted to 150 W and the coil power of the helicon sputtering was adjusted to 50 W to form the plasma of the gases for bombarding the aluminum target (99.999% purity). The sputtering operation was performed for 150 minutes, and a single-crystal aluminum nitride having the thickness of about 335 nm was formed.

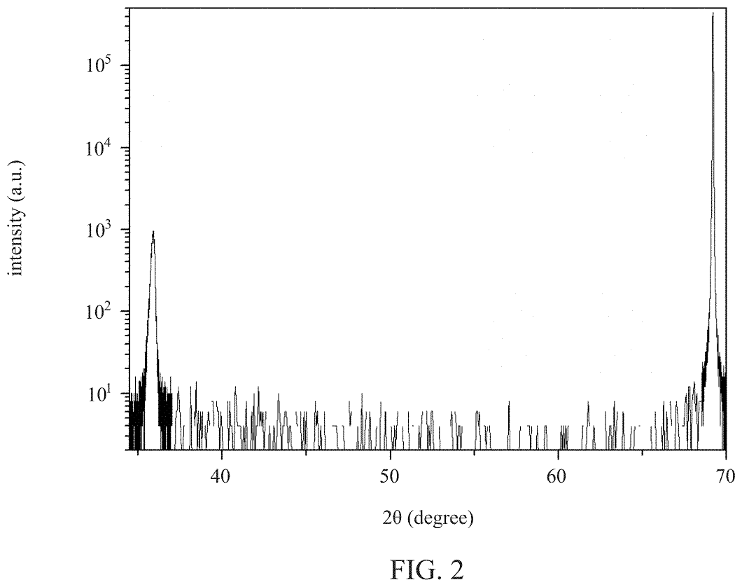

Referring to FIG. 2, FIG. 2 is an X-ray diffraction (XRD) spectrum in the θ-2θ scan of a single-crystal aluminum nitride layer of an example. A lattice plane of the single-crystal aluminum nitride layer can be observed in FIG. 2. In the 2θ scan, a significant peak is observed at 2θ=35.86° (which corresponds to a plane of AlN(0002)). In other words, the single-crystal aluminum nitride layer with high quality has a c-axis oriented hexagonal wurtzite structure (i.e., AlN[0001]∥Si[001]). A signal of the MoS₂ is not observed because the thickness of the MoS₂ is extremely thin.

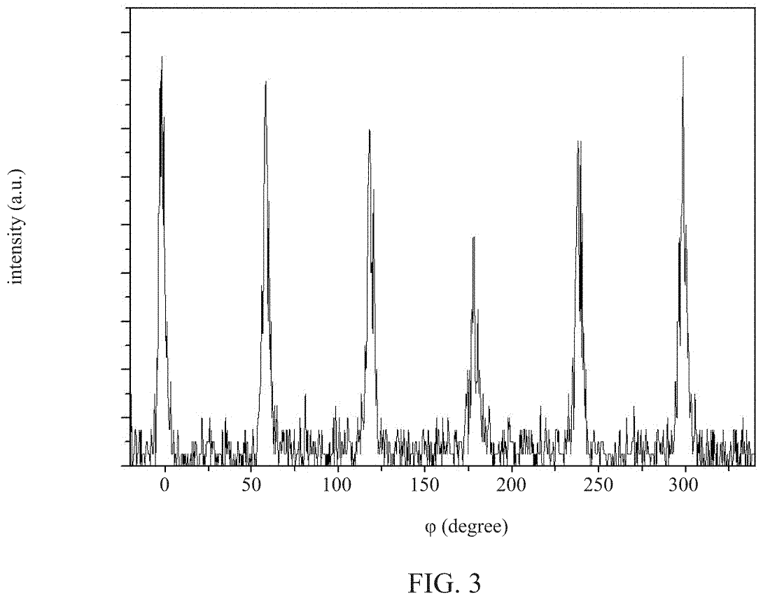

Referring to FIG. 3, FIG. 3 is an XRD spectrum in the φ scan of a single-crystal aluminum nitride layer of an example. In FIG. 3, six peaks of AlN(101̅1) separated from adjacent one another by 60 degrees are observed. The six-fold symmetry proves that the aluminum nitride layer of the example is c-axis oriented and has a single crystal structure because the crystal structure of an aluminum nitride crystal belongs to the hexagonal crystal structure.

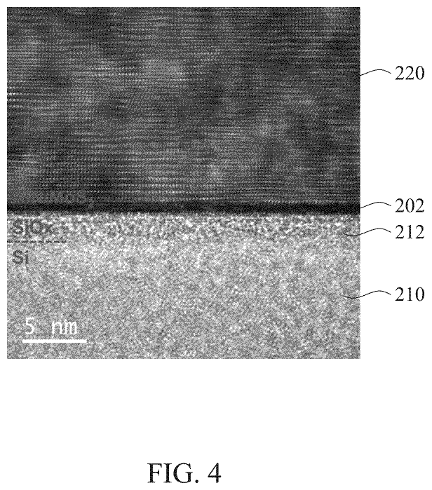

Next, referring to FIG. 4, FIG. 4 is a high-resolution transmission electron microscopy (TEM) image of a structure of AlN/MoS₂/Si. In FIG. 4, a reference number 210 represents the silicon substrate, a reference number 212 represents the silicon oxide layer on the silicon substrate, a reference number 202 represents a MoS₂ layer and a reference number 220 represents the single-crystal aluminum nitride layer. The silicon oxide layer 212 may be an oxide layer naturally formed during the process, and its thickness is about 2.5 nm. In the high-resolution TEM image of FIG. 4, an arrangement of atoms can be observed, in which merely a small number of dislocations are observed in the single-crystal aluminum nitride layer 220. The sample formed in the example has the thickness of about 80 nm and a length of about 510 nm, and a dislocation density calculated using these parameters is about 7.4×10⁹ cm⁻². The result is better than the dislocation density (about 10¹⁰ cm⁻²) of the aluminum nitride layer formed by using the typical techniques. Moreover, the single-crystal aluminum nitride layer 220 can be observed in FIG. 4, while the portion of the silicon substrate 210 is blurred. This indicates that the silicon substrate 210 is not aligned with the single-crystal aluminum nitride layer 220 in ab plane, such that injected electrons cannot move along the crystal axis of both the aluminum nitride and silicon. That is, the single-crystal aluminum nitride layer of the example is epitaxially grown on the MoS₂, but is not epitaxially grown on the silicon substrate.

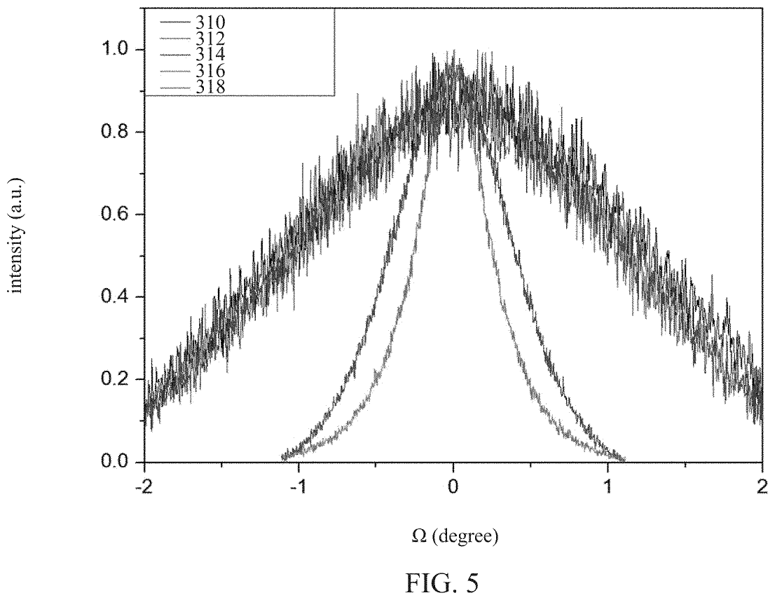

Please refer to FIG. 5. FIG. 5 shows the XRD rocking curves of aluminum nitrides formed by various methods, in which a curve 310 represents the aluminum nitride directly grown on a Si(100) silicon substrate, a curve 312 represents the aluminum nitride grown on a Si(111) silicon substrate, a curve 314 represents the aluminum nitride grown on a sapphire substrate, a curve 316 represents the single-crystal aluminum nitride layer of the example, and a curve 318 represents the aluminum nitride grown on graphene that is grown on a silicon substrate. As shown in FIG. 5, full width at half maximum (FWHM) of the curve 316 is 0.336°, which is narrower than the FWHM of the aluminum nitrides of curves 310, 312 and 314.

As shown in the curve 318, similar to the MoS₂ be transferred onto the silicon substrate, the graphene layer is also formed on the remote substrate first, and then the graphene layer is transferred onto the silicon substrate. However, the single-crystal aluminum nitride layer cannot be grown on the graphene layer because the lattice mismatch between the graphene and the aluminum nitride is still large.

In another comparative example, compared to the MoS₂ formed by using the transferring operation, the MoS₂ is directly grown on the Si(100) substrate. However, the MoS₂ cannot form the hexagonal crystal structure, such that the single-crystal aluminum nitride cannot be formed on the MoS₂ of this comparative example.

According to the results above, the single-crystal aluminum nitride layer with a satisfactory quality can be formed on the MoS₂/silicon substrate at a low temperature. The MoS₂/silicon substrate is formed by transferring the MoS₂ onto the silicon substrate in the method of forming the single-crystal group-III aluminum nitride of the present invention. The c-axis oriented single-crystal structure of AlN/MoS₂/Si of the present invention can be applied to the photoelectric devices such as laser, light-emitting diode, an optical detector or a combination of a photoelectric device and an integrated circuit (IC).

Although the present invention has been described in considerable detail concerning certain embodiments thereof, while it is not intended to limit the present invention. It will be apparent to those skilled in the art that various modifications and variations can be made to the structure of the present invention without departing from the scope or spirit of the invention. Therefore, the spirit and scope of the appended claims should not be limited to the description of the embodiments contained herein.

What is claimed is:

1. A method of forming a single-crystal group-III nitride, the method comprising:
forming molybdenum disulfide (MoS₂) on a remote substrate;
transferring the MoS₂ onto a substrate; and
performing a sputtering operation on the MoS₂, wherein a mixture gas of nitrogen gas and an inert gas is introduced and a plasma of the mixture gas is formed to bombard an aluminum target, thereby epitaxially depositing a single-crystal group-III nitride layer on the MoS₂.

2. The method of claim 1, wherein the sputtering operation is performed under a working pressure of 1.2×10⁻² pa to 2.6×10⁻² pa.

3. The method of claim 1, wherein forming the MoS₂ comprises:
placing the remote substrate in a reaction chamber; and
introducing a molybdenum (Mo)-containing precursor and a sulfur (S)-containing precursor into the reaction chamber, thereby depositing the MoS₂ on the remote substrate.

4. The method of claim 1, wherein the substrate comprises a silicon substrate, a flexible substrate, a sapphire substrate or a silicon carbide substrate.

5. The method of claim 1, wherein the sputtering operation is performed under a background pressure that is equal to or smaller than 7.0×10⁻⁵ pa.

6. The method of claim 1, wherein a power on the aluminum target in the sputtering operation is 100 W to 200 W.

7. The method of claim 1, wherein a ratio of a flow rate of the inert gas with respect to a flow rate of the nitrogen gas is 3:1 to 1:3.

8. The method of claim 1, wherein a thickness of the MoS₂ is in a range from 0.7 nm to 2.5 nm.

9. The method of claim 1, further comprising forming a gallium nitride layer on the single-crystal group-III nitride layer, wherein no operation with a reaction temperature greater than 500° C. is performed between forming the single-crystal group-III nitride layer and forming the gallium nitride layer.

10. The method of claim 1, wherein the single-crystal group-III nitride layer is c-axis oriented aluminum nitride (AlN).
